(19) United States
(12) Patent Application Publication
(10) Pub. No.: US 2026/0341377 A1
(43) Pub. Date: Oct. 29, 2026

(54) MEDIA SCAN FOR PROGRAM/ERASE DISTURB IN BLOCK-BY-DECK IN A MEMORY SUB-SYSTEM

(71) Applicant: Micron Technology, Inc., Boise, ID (US)

(72) Inventors: Dongxiang Liao, Sunnyvale, CA (US); Xiangang Luo, Fremont, CA (US)

(21) Appl. No.: 19/188,727

(22) Filed: Apr. 24, 2025

(51) Int. Cl. G11C 16/34; G11C 16/32

(52) U.S. Cl. CPC G11C 16/3431; G11C 16/32; G11C 16/3495

(57) ABSTRACT

A processing device in a memory system detects an occurrence of a triggering event and identifies a portion of a block of a memory device. The processing device performs a scan of the portion of the block, where performing the scan includes performing a first read operation at a first voltage offset level to determine a first reliability metric and performing a second read operation a second voltage offset level to determine a second reliability metric. The processing device determines whether the first reliability metric satisfies a first threshold criterion and whether the second reliability metric satisfies a second threshold criterion. Responsive to determining that either the first reliability metric satisfies the first threshold criterion or the second reliability metric satisfies the second threshold criterion, the processing device sends an instruction to the memory device to cause the portion of the block to be refreshed.

### TECHNICAL FIELD

Embodiments of the disclosure relate generally to memory sub-systems, and more specifically, relate to media scanning for program/erase disturb in block-by-deck in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 is a diagram illustrating a memory array of a multi-deck memory device, in accordance with some embodiments of the present disclosure.

FIG. 3 is a graph depicting an example read-write-bit (RWB) margin and voltage offset levels associated with a deck of a block, in accordance with some embodiments of the present disclosure.

FIG. 4 is a flow diagram of an example method for performing a media scan for program/erase disturb in block-by-deck in accordance with some embodiments of the present disclosure.

FIG. 5 is a block diagram of an example computer system in which embodiments of the present disclosure may operate.

### DETAILED DESCRIPTION

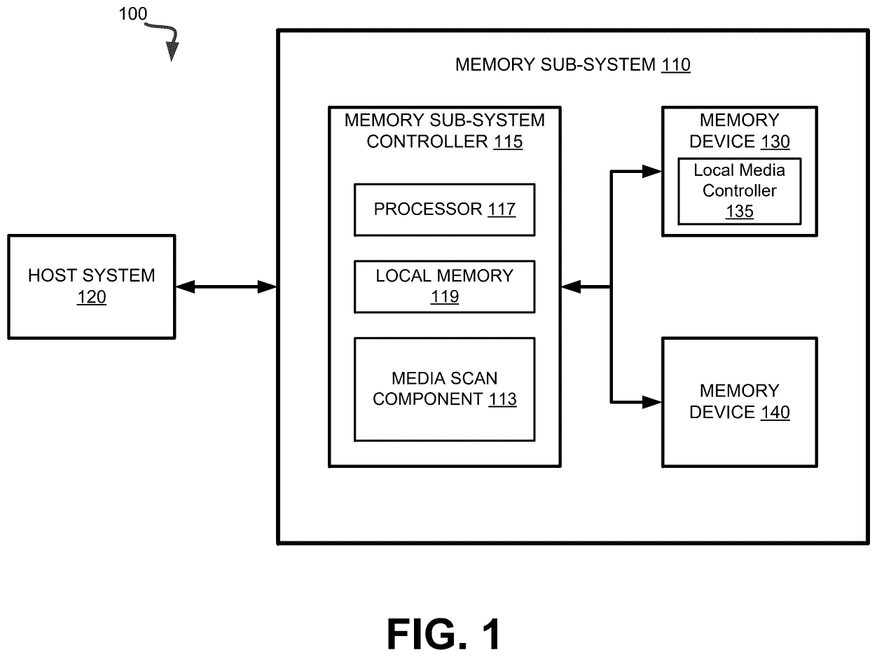

Aspects of the present disclosure are directed to media scanning for program/erase disturb in block-by-deck in a memory sub-system. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

A desire for increased storage capacity in memory devices drives an expansion of block sizes, including an increase of the number of wordlines in each block. The presence of such additional wordlines, however, presents certain challenges including, for example, performance and reliability penalties attributable to various inefficiencies (e.g., associated with garbage collection or other media management operations for the increased block size). Certain memory devices are thus divided into multiple segments, sometimes referred to as “decks.” For example, a memory device could include a top (or “upper”) deck and a bottom (or “lower”) deck, each including a respective set of wordlines from the block. Other memory devices can include more than two decks. In some instances, the separate decks are individually accessible, such that a memory access operation (i.e., a program, read, or erase operation) could be performed on one deck without impacting memory cells of the other deck. The functionality can be referred to as the “block-by-deck” feature.

When such a memory access operation is performed on one deck of the memory device using the block-by-deck feature, there is a need to preserve the state of the memory cells in the other deck(s). During a programming operation on one deck, for example, a selected memory cell(s) can be programmed with the application of a programming voltage to a selected wordline. Due to the wordline being common to multiple memory cells, unselected memory cells can be subject to the same programming voltage as the selected memory cell(s). If not otherwise preconditioned, the unselected memory cells can experience effects from the programming voltage on the common wordline. These programming voltage effects can include the condition of charge being stored in the unselected memory cells which are expected to maintain stored data. This programming voltage effect is termed a “program/erase disturb” effect. The program/erase disturb effect can render the charge stored in the unselected memory cells unreadable altogether or, although still apparently readable, the contents of the memory cell can be read as a data value different than the intended data value stored before application of the programming voltage. Thus, when a memory access operation is performed on a single deck in a block, other decks in the block can experience a program/erase disturb effect that causes stored data in the other blocks to be lost or corrupted.

As such, conventional systems track a program/erase count (PEC) offset between decks in a block (e.g., a difference between the number of times a deck is cycled as compared to other decks in the block) to determine when to refresh data in a deck in the block by copying the data to another deck in the block. A memory sub-system can maintain a table, or other data structure, indicating the PEC offset of each deck in a block and use the table to determine when to refresh a deck by identifying decks with a cumulative PEC offset that exceed a PEC threshold. For example, in a block with three decks, a memory sub-system can have a PEC offset threshold of 200 program/erase cycles. After the middle deck is cycled 50 times and the bottom deck is cycled 150 times, the top deck, which was not cycled, will reach a cumulative PEC offset of 200 program/erase cycles from the middle and bottom decks. Thus, the memory sub-system can determine to refresh the top deck of the block. After the top deck is refreshed, the PEC offset of the top deck can be reset from 200 program/erase cycles to 0 program/erase cycles. In another example, the top deck can be cycled 200 times, while the middle and bottom decks are not cycled. The memory sub-system can then refresh the middle and bottom deck and reset the PEC offsets of the middle and bottom deck to 0 program/erase cycles.

The PEC offset threshold, however, is a predetermined threshold based on a die with low resilience (e.g., a die that is more susceptible to program/erase disturb and may lose data when the PEC offset reaches 200 program/erase cycles). For dies with more resilience (e.g., dies that can handle a PEC offset of over 200 program/erase cycles without experiencing significant program/erase disturb effects), the low PEC offset threshold can cause refresh operations to be performed prematurely, increasing the total amount of refresh operations performed. The process of refreshing a deck can consume computing power to access the deck and write the data to a separate location within the block. As such, performing unnecessary refresh operations on decks can consume significant computing power and contribute to the total bytes written (TBW), or the amount of data that can be written to a memory device before the device experiences wear and decreased reliability. Additionally, tracking the PEC offset of each deck in the memory device to determine when a cumulative PEC offset exceeds the PEC offset threshold consumes memory space and processing power (e.g., to maintain and update a table of PEC offset values for each deck in a block). Thus, managing program/erase disturb in a memory device including blocks with multiple decks can consume computing power, memory space, processing power, and unnecessarily increase the TBW.

Aspects of the present disclosure address the above and other deficiencies by providing a memory sub-system that performs media scans for program/erase disturb in block-by-deck blocks. In one embodiment, processing logic in a memory sub-system detects an occurrence of a triggering event (e.g., the expiration of a specified time interval) and identifies a portion of a block (e.g., a deck). The processing logic performs a scan of the portion of the block, which includes performing a first read operation at a first voltage offset level to determine a first reliability metric (e.g., bit error count) and a second read operation at a second voltage offset level to determine a second reliability metric. In some embodiments, the first voltage offset level can be below (i.e., at a lower voltage than) a default read voltage level associated with the portion of the deck and the second voltage offset level can be above (i.e., at a higher voltage than) the default read voltage level. The processing logic can then determine whether the first reliability metric satisfies a first threshold criterion and whether the second reliability metric satisfies a second threshold criterion. For example, processing logic can determine whether the first reliability metric exceeds a first error threshold to satisfy the first threshold criterion and whether the second reliability metric exceeds a second error threshold to satisfy the second threshold criterion, in some embodiments. Upon determining that either the first threshold criterion is satisfied or the second threshold criterion is satisfied, processing logic in the memory sub-system can send an instruction to the memory device to cause the portion of the block to be refreshed (e.g., for data in the deck to be written to a separate portion of the block).

Advantages of the present disclosure include, but are not limited to, improving the system performance and reducing the TBW. By determining when to refresh a portion of a block (e.g., a deck) based on whether a reliability metric exceeds an error threshold, the amount of refresh operations is reduced because decks are refreshed after a loss of a read-write bit margin (e.g., a voltage range that separates read and write operations in memory cells) is detected. For example, a first deck with a PEC offset of 200 program/erase cycles but with a first reliability metric and a second reliability metric that do not exceed the respective error thresholds will not be refreshed. However, a second deck with a PEC offset of 200 program/erase cycles and with a first reliability metric that exceeds a first error threshold can be refreshed. As such, the amount of refresh operations performed is reduced because one deck would be refreshed rather than two. The reduction in refresh operations can reduce the amount of processing power used to refresh decks, which can be allocated to other processes to improve system efficiency. By reducing the amount of refresh operations, less write operations are performed to copy data between decks, which also allows for additional write operations to be performed by other processes before reaching the TBW limit. Additionally, the determination to refresh the block is based on the scan and does not use the PEC offset between decks in a block, conserving memory space and computing power previously spent tracking the PEC offset between decks. The additional memory space and computing power can be allocated to other processes, further improving the system performance and efficiency.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a media scan component 113 that can perform a media scan for program/erase disturb in block-by-deck blocks (e.g., a block with 2D arrays of memory cells electronically and individually addressable by a vertical access line). Program/erase disturb refers to when voltage from a programming and/or erase operation performed on one deck affects the other decks in the block, causing data in the other blocks to become corrupted or lost. In some embodiments, the memory sub-system controller 115 includes at least a portion of the media scan component 113. In some embodiments, the media scan component 113 is part of the host system 120, an application, or an operating system. In other embodiments, local media controller 135 includes at least a portion of media scan component 113 and is configured to perform the functionality described herein.

The media scan component 113 can detect an occurrence of a triggering event (e.g., the expiration of a specified period of time). In some embodiments, the media scan component 113 can identify a portion of a block of a memory device 130 (e.g., a deck of the memory block) and perform a scan of the identified portion of the block. In some embodiments, performing a scan can include performing a first read operation at a first voltage offset level (e.g., from a default read voltage) to determine a first reliability metric (e.g., a bit error count) and performing a second read operation at a second voltage offset level to determine a second reliability metric. The media scan component 113 can then determine whether the first reliability metric satisfies a first threshold criterion and whether the second reliability metric satisfies a second threshold criterion. For example, in some embodiments, the media scan component 113 can determine whether the first reliability metric exceeds a first error threshold to satisfy the first threshold criterion and whether the second reliability metric exceeds a second error threshold to satisfy the second threshold criterion. Upon determining that either the first threshold criterion is satisfied or the second threshold criterion is satisfied, the media scan component 113 can send an instruction to the memory device to cause a portion of the block to be refreshed. Further details with regards to the operations of the media scan component 113 are described below.

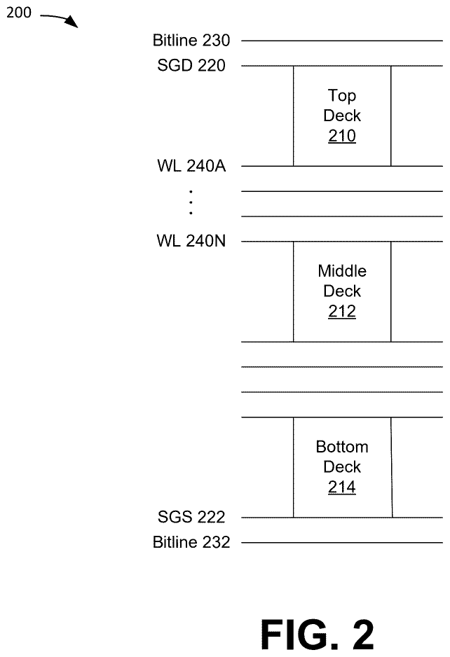

FIG. 2 is a diagram illustrating a memory array 200 of a multi-deck memory device, such as memory device 130, in accordance with some embodiments of the present disclosure. In some embodiments, the memory array 200 can include a top deck 210, a middle deck 212, and a bottom deck 214. Each deck includes a corresponding set of wordlines that are coupled to memory cells arranged in memory strings. In one embodiment, the top deck 210 is arranged vertically above the middle deck 212, which is arranged vertically above the bottom deck 214, such that the memory strings can extend from a drain (e.g., bitline 230 accessible via a drain select line (SGD) 220) adjacent to the top deck 210, through the middle deck 212, to a source (e.g., bitline 232 accessible via a source select line (SGS) 222) adjacent to the bottom deck 214 of the memory array. In other embodiments there can be some other number or arrangement of decks in the memory device 130. In some embodiments, each deck can be separated by wordlines 240A-240N, which can be dummy wordlines (i.e., wordlines not used to store host data).

In some embodiments, the media scan component 113 can perform a scan on each deck in the block upon detecting a single triggering event. For example, the media scan component 113 can detect that a specified time interval (e.g., 24 hours) has passed and perform a scan on the top deck 210. The scan can include performing a first read operation at a first voltage offset level to determine a first reliability metric (e.g., bit error count) and a second read operation at a second voltage offset level to determine a second reliability metric. The media scan component 113 can then determine whether either reliability metric satisfies a respective threshold criterion. If either threshold criterion is satisfied, then the media scan component 113 can send an instruction to the memory device to refresh the top deck 210 (e.g., copy data from the top deck 210 to bottom deck 214) without refreshing the middle deck 212 or bottom deck 214. The media scan component 113 can then perform the scan on another deck (e.g., middle deck 212). It should be noted that the order in which the decks are scanned in the example is for illustrative purposes and can vary based on the embodiment (e.g., the middle deck 212 or bottom deck 214 can be scanned first, in some embodiments). In other embodiments, each deck may have a separate triggering event. For example, a first period of time can be associated with the top deck 210 and a second period of time can be associated with the middle deck 212. After the passage of the first period of time, the media scan component 113 can perform a scan of the top deck 210 to determine whether to refresh the top deck 210. After the passage of the second period of time, the media scan component 113 can perform a scan of the middle deck 212.

In some embodiments, the media scan component 113 can perform a partial scan of a deck in the block. For example, the media scan component 113 can perform a first read operation on the middle deck 212 at the first voltage offset level to determine a first reliability metric. The media scan component 113 can then determine whether the first reliability metric satisfies a first threshold criterion and refresh the middle deck 212 if the first threshold criterion is satisfied. The media scan component 113 can then perform a second read operation at a second voltage offset level after detecting a separate triggering event (e.g., the passage of another specified period of time), in some embodiments. In some embodiments, the media scan component can perform a first read operation for each deck in the block after a first triggering event (e.g., the passage of a first periodic interval), then perform a second read operation for each deck after a second triggering event (e.g., the passage of a second period of time, the completion of a first read operation for each deck). For example, after the passage of a first time interval, a first read operation can be performed on each of the top deck 210, middle deck 212, and bottom deck 214. The media scan component 113 can then determine whether to refresh each deck based on whether the corresponding first reliability metric satisfies the first threshold criterion. After the passage of a second time interval, the media scan component 113 can perform a second read operation on each of the top deck 210, middle deck 212, and bottom deck 214. The media scan component 113 can then determine whether the corresponding second reliability metric for each deck satisfies the second threshold criterion and refresh the decks based on the determination.

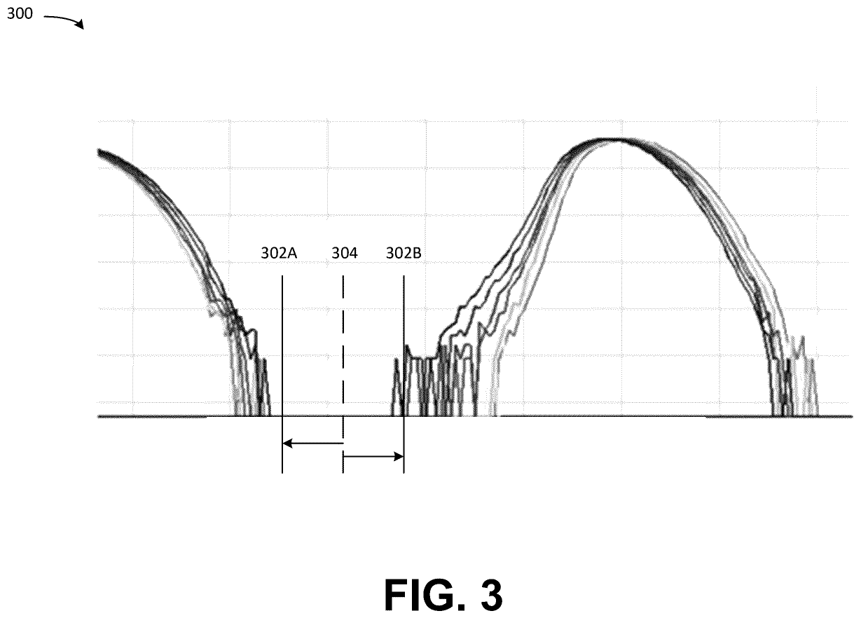

FIG. 3 is a graph 300 depicting an example read-write-bit (RWB) margin and voltage offset levels associated with a deck of a block (e.g., in memory array 200), in accordance with embodiments of the present disclosure. An RWB margin refers to a voltage margin between programming distributions of memory cells in a portion of a block (e.g., a deck). The horizontal axis of the graph 300 depicts voltage levels and the vertical axis represents a number of memory cells programmed to the different voltage levels. In some embodiments, upon detecting the triggering event and identifying a portion of the block (e.g., a deck), the media scan component 113 can determine a default read voltage level 304 associated with the deck. For example, in some embodiments, the media scan component 113 can maintain a table indicating read voltages for each deck in the memory device 130, which the media scan component 113 can use to determine the default read voltage level. For example, the default read voltage level may be set in the read window between two adjacent programming distributions. The media scan component 113 can then determine the first voltage offset level 302A and the second voltage offset level 302B based on the default read voltage level 304, in some embodiments. For example, the first voltage offset level 302A can be a first specified offset value below (i.e., at a lower voltage than) the default read voltage level 304 and the second voltage offset level 302B can be a second specified offset value above (i.e., at a higher voltage than) the default read voltage level 304. Depending on the embodiment, the first and second specified offset values can be identical in magnitude.

In some embodiments, the first and second specified offset values can be determined based on component qualification data (e.g., the voltage margin between programming distributions representing different data states, such as 0 and 1, in a memory cell) and/or performance and reliability metrics (e.g., a performance margin, or a value indicating the extra capacity a system has above a minimum performance threshold). For example, a larger voltage margin can create a larger distinction between the read voltage and write voltage, producing a larger RWB margin. As such, larger specified offset values van be used during a scan to reflect a larger RWB margin. In contrast, a memory sub-system with a smaller voltage margin can use smaller specified offset values to reflect the smaller RWB margin. In another example, a memory sub-system that maintains a performance margin for a longer period of time (e.g., one year) can have a larger RWB margin to compensate for increased degradation and wear on memory cells caused by operating at higher speeds for a longer period of time to meet the performance margin. Thus, a larger specified offset value can be used during the scan. A memory sub-system that updates performance margins more frequently (e.g., monthly) can have less degradation and wear on the memory cells because the operating speeds of memory cells are adjusted more often, leading to a smaller RWB margin and smaller specified offset values.

Upon determining the voltage offset levels (e.g., based on the default read offset and specified offset values), the media scan component 113 performs a first read operation at the first voltage offset level 302A to determine a first reliability metric and a second read operation at the second voltage offset level 302B to determine a second reliability metric. The reliability metric can refer to the BEC. In some embodiments, the media scan component 113 can determine whether each reliability metric satisfies a respective threshold criterion by determining whether each reliability metric exceeds an error threshold. For example, the media scan component 113 can determine whether the first reliability metric exceeds a first error threshold and whether the second reliability metric exceeds a second error threshold, which indicates that the RWB margin is decreasing because program/erase disturb is affecting the identified portion of the block (e.g., deck) by shifting the voltage thresholds for read and write operations. In some embodiments, the first error threshold and the second error threshold can be the same value. If either threshold is exceeded, the media scan component 113 can send an instruction to the memory device to cause the deck to be refreshed, in some embodiments.

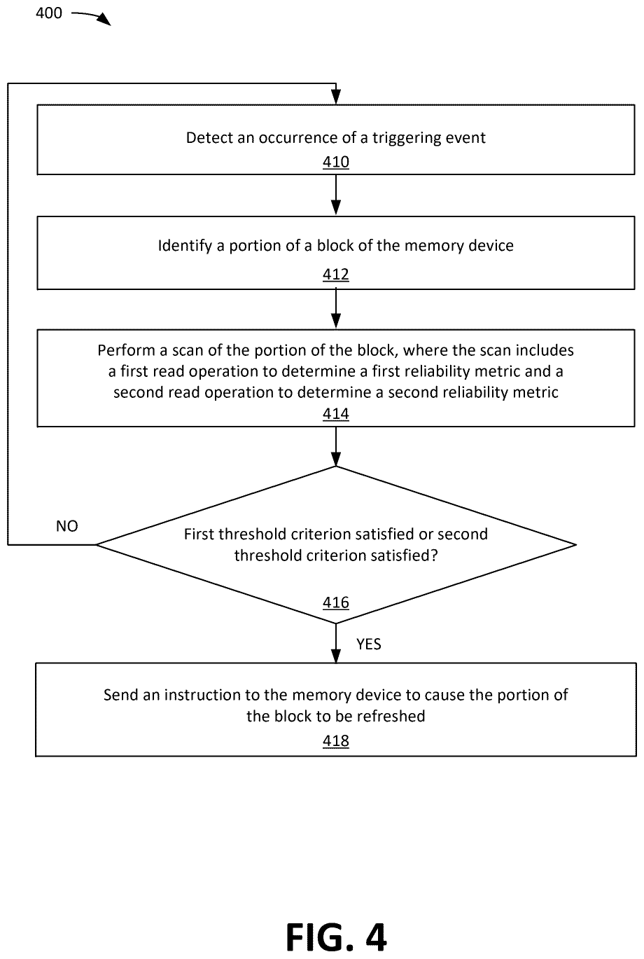

FIG. 4 is a flow diagram of an example method 400 for media scanning for program/erase disturb in block-by-deck in a memory sub-system, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the media scan component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 410, the processing logic detects an occurrence of a triggering event. In some embodiments, detecting the occurrence of the triggering event includes detecting an expiration of a periodic interval (e.g., a specified period of time) or the occurrence of a certain time of day. For example, in some embodiments, the media scan component 113 can use a system clock to detect when the time reaches midnight to perform a scan of a deck. In other or similar embodiments, the media scan component 113 can determine that receiving an instruction to perform a scan (e.g., from the host system) is a triggering event. In other embodiments, a triggering event can be the occurrence of a specified event. For example, in some embodiments, the media scan component 113 can determine when a high-temperature process, such as soldering, occurs and identify a portion of a block (e.g., a deck) to perform a scan.

At operation 412, the processing logic identifies a portion of a block of the memory device. In some embodiments, a portion of a memory device is a deck. For example, in a memory device with a memory array including a top deck, a middle deck, and a bottom deck, a portion of the memory device can be one of the three decks. In some embodiments, more than one portion of a block can be identified for separate scans based on the triggering event. For example, the passage of a specified time interval can cause a top deck, middle deck, and bottom deck to each be subject to a scan, as described in FIG. 2. In other embodiments, different portions of a block can be associated with different triggering events. For example, a top deck can be associated with a first specified time interval, and a bottom deck can be associated with a second specified time interval.

At operation 414, the processing logic performs a scan of the portion of the block. The scan includes performing a first read operation at a first voltage offset level (e.g., first voltage offset level 302A) to determine a first reliability metric and performing a second read operation at a second voltage offset level (e.g., second voltage offset level 302B) to determine a second reliability metric. In some embodiments, the first voltage offset level 302A and second voltage offset level 302B can be based on a default read voltage 304 that is associated with the block. For example, the first voltage offset level 302A is a voltage that is a first specified value (e.g., specified offset value) below the default read voltage 304 and the second voltage offset level 302B is a voltage that is a second specified value above the default read voltage 304, as described in FIG. 3. In some embodiments, the first and second offset values can be the same value. A media scan component 113 can determine the specified offset values based on component qualification data and/or performance and reliability metrics, in some embodiments.

At operation 416, the processing logic determines whether the first reliability metric satisfies a first threshold criterion and whether the second reliability metric satisfies a second threshold criterion. In some embodiments, satisfying the first threshold criterion includes determining whether the first reliability metric exceeds a first error threshold and satisfying a second threshold criterion includes determining whether the second reliability metric exceeds a second error threshold. In some embodiments, the first error threshold is equal to the second error threshold. Upon determining that either the first threshold criterion or the second threshold criterion is satisfied, processing logic proceeds to operation 418. Otherwise, processing logic proceeds to operation 410, in some embodiments.

As described in FIG. 2, in some embodiments the media scan component 113 can perform a portion of a scan. For example, after the occurrence of a first triggering event, the media scan component 113 can perform a first read operation at a first voltage offset 302A and determine whether the first reliability metric satisfies a first threshold criterion to determine whether to refresh the deck. After the occurrence of a second triggering event, the media scan component 113 can then perform a second read operation at a second voltage offset 302B to determine whether the refresh the deck based on the second reliability metric.

At operation 418, the processing logic sends an instruction to the memory device to cause the portion of the block to be refreshed. In some embodiments, refreshing the block can include copying data in the portion of the block (e.g., a deck) to separate portion of the block (e.g., a separate deck). For example, in one embodiment, data in a deck can be read and written to a separate deck in the same block. In other embodiments, refreshing a deck can include copying data in a deck to a separate block.

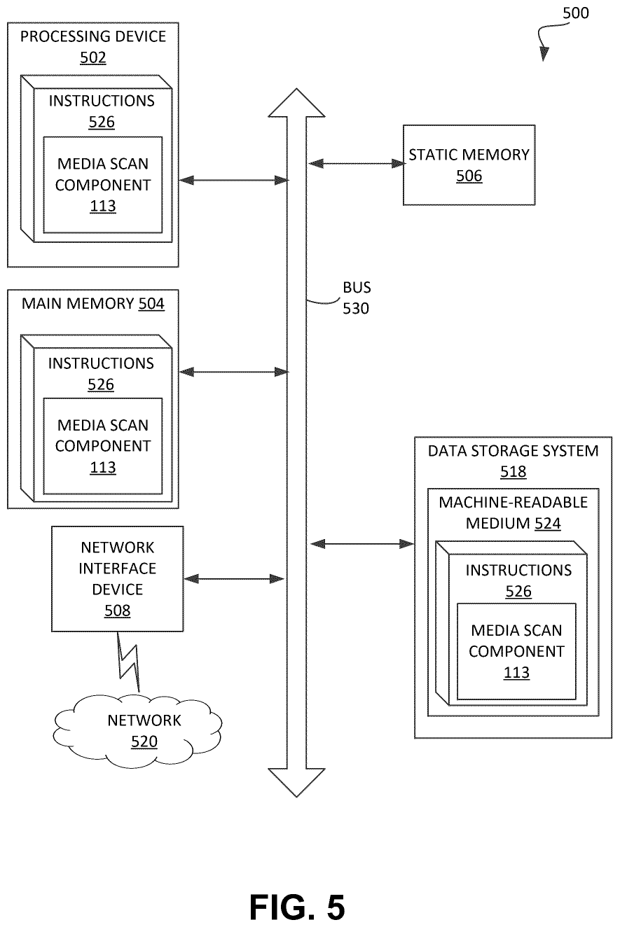

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media scan component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or RDRAM, etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a media scan component (e.g., the media scan component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled to the memory device, to perform operations comprising:
detecting an occurrence of a triggering event;
responsive to the occurrence of the triggering event, identifying a portion of a block of the memory device;
performing a scan of the portion of the block, wherein performing the scan comprises performing a first read operation at a first voltage offset level to determine a first reliability metric and performing a second read operation at a second voltage offset level to determine a second reliability metric;
determining whether the first reliability metric satisfies a first threshold criterion and whether the second reliability metric satisfies a second threshold criterion; and
responsive to determining that either the first reliability metric satisfies the first threshold criterion or the second reliability metric satisfies the second threshold criterion, sending an instruction to the memory device to cause the portion of the block to be refreshed.

2. The system of claim 1, wherein detecting the occurrence of the triggering event comprises detecting an expiration of a periodic interval.

3. The system of claim 1, wherein determining whether the first reliability metric satisfies a first threshold criterion and whether the second reliability metric satisfies a second threshold criterion comprises:
determining whether the first reliability metric exceeds a first error threshold; and
determining whether the second reliability metric exceeds a second error threshold.

4. The system of claim 3, wherein the first error threshold is equal to the second error threshold.

5. The system of claim 1, wherein sending an instruction to the memory device to cause the portion of the block to be refreshed comprises:
sending an instruction to the memory device to cause data in the portion of the block to be copied to a separate portion of the block.

6. The system of claim 1, wherein the portion of the memory device comprises a top deck, a middle deck, or a bottom deck of a memory array.

7. The system of claim 1, wherein the processing device is to perform operations further comprising:
determining a default read voltage associated with the portion of the block;
determining the first voltage offset level based on the default read voltage, wherein the first voltage offset level is lower than the default read voltage; and
determining the second voltage offset level based on the default read voltage, wherein the second voltage offset level is higher than the default read voltage.

8. A method comprising:
detecting an occurrence of a triggering event;
identifying a portion of a block of a memory device;
performing a scan of the portion of the block, wherein performing the scan comprises performing a first read operation at a first voltage offset level to determine a first reliability metric and performing a second read operation at a second voltage offset level to determine a second reliability metric;
determining whether the first reliability metric satisfies a first threshold criterion and whether the second reliability metric satisfies a second threshold criterion; and
responsive to determining that either the first reliability metric satisfies the first threshold criterion or the second reliability metric satisfies the second threshold criterion, sending an instruction to the memory device to cause the portion of the block to be refreshed.

9. The method of claim 8, wherein detecting the occurrence of the triggering event comprises detecting an expiration of a periodic interval.

10. The method of claim 8, wherein determining whether the first reliability metric satisfies a first threshold criterion and whether the second reliability metric satisfies a second threshold criterion comprises:
determining whether the first reliability metric exceeds a first error threshold; and
determining whether the second reliability metric exceeds a second error threshold.

11. The method of claim 10, wherein the first error threshold is equal to the second error threshold.

12. The method of claim 8, wherein sending an instruction to the memory device to cause the portion of the block to be refreshed comprises:
sending an instruction to the memory device to cause data in the portion of the block to be copied to a separate portion of the block.

13. The method of claim 8, wherein the portion of the memory device comprises a top deck, a middle deck, or a bottom deck of a memory array.

14. The method of claim 8, further comprising:
determining a default read voltage associated with the portion of the block;
determining the first voltage offset level based on the default read voltage, wherein the first voltage offset level is lower than the default read voltage; and
determining the second voltage offset level based on the default read voltage, wherein the second voltage offset level is higher than the default read voltage.

15. A non-transitory computer-readable storage medium comprising instructions that, when executed by a processing device, cause the processing device to perform operations comprising:
detecting an occurrence of a triggering event;
identifying a portion of a block of a memory device;
performing a scan of the portion of the block, wherein performing the scan comprises performing a first read operation at a first voltage offset level to determine a first reliability metric and performing a second read operation at a second voltage offset level to determine a second reliability metric;
determining whether the first reliability metric satisfies a first threshold criterion and whether the second reliability metric satisfies a second threshold criterion; and
responsive to determining that either the first reliability metric satisfies the first threshold criterion or the second reliability metric satisfies the second threshold criterion, sending an instruction to the memory device to cause the portion of the block to be refreshed.

16. The non-transitory computer-readable storage medium of claim 15, wherein detecting the occurrence of the triggering event comprises detecting an expiration of a periodic interval.

17. The non-transitory computer-readable storage medium of claim 15, wherein determining whether the first reliability metric satisfies a first threshold criterion and whether the second reliability metric satisfies a second threshold criterion comprises:
determining whether the first reliability metric exceeds a first error threshold; and
determining whether the second reliability metric exceeds a second error threshold.

18. The non-transitory computer-readable storage medium of claim 17, wherein the first error threshold is equal to the second error threshold.

19. The non-transitory computer-readable storage medium of claim 15, wherein sending an instruction to the memory device to cause the portion of the block to be refreshed comprises:
sending an instruction to the memory device to cause data in the portion of the block to be copied to a separate portion of the block.

20. The non-transitory computer-readable storage medium of claim 15, wherein the portion of the memory device comprises a top deck, a middle deck, or a bottom deck of a memory array.
